(19) United States
(12) Patent Application Publication
(10) Pub. No.: US 2026/0371627 A1
(43) Pub. Date: Nov. 19, 2026

(54) SEMICONDUCTOR DEVICE HAVING PATTERNS

(71) Applicant: Samsung Electronics Co., Ltd., Suwon-si (KR)

(72) Inventors: Jeewoong Kim, Suwon-si (KR); Jinkyu Kim, Suwon-si (KR); Yunsuk Nam, Suwon-si (KR); Haein Shin, Suwon-si (KR); Inho Yeo, Suwon-si (KR); Yunju Cho, Suwon-si (KR)

(73) Assignee: Samsung Electronics Co., Ltd., Suwon-si (KR)

(21) Appl. No.: 19/452,190

(22) Filed: Jan. 16, 2026

(30) Foreign Application Priority Data
May 16, 2025 (KR) 10-2025-0064183

(51) Int. Cl. H10D 12/00; H10D 62/17

(52) U.S. Cl. CPC H10D 12/481; H10D 62/177

(57) ABSTRACT

A semiconductor device according to embodiments may include a lower layer comprising a lower insulating layer and a semiconductor layer located on at least a portion of an upper surface of the lower insulating layer, a lower pattern located on the lower layer, the lower pattern comprising a first region comprising a semiconductor material and a second region located between the lower layer and the first region and comprising an insulating material, and a first collector pattern and a first emitter pattern located apart from one another along a first direction parallel to the upper surface of the lower layer, wherein the semiconductor layer and the first region constitute at least a portion of a body portion, and a first thickness of the body portion in a vertical direction under the first collector pattern is smaller than a second thickness of the body portion in the vertical direction under the first emitter pattern.

### CROSS-REFERENCE TO RELATED APPLICATIONS

This present application claims priority to and the benefit under 35 U.S.C. § 119(a)-(d) of Korean Patent Application No. 10-2025-0064183, filed on May 16, 2025, in the Korean Intellectual Property Office, the entire disclosure of which is incorporated herein by reference.

### FIELD

The present disclosure relates to a semiconductor device and more particularly to a semiconductor device having patterns.

### BACKGROUND

A semiconductor device may be vulnerable to ESD (Electrostatic Discharge) that may occur during manufacturing, inspection, assembly, transportation, or operation processes, and such ESD may cause circuit damage or device destruction. Accordingly, in order to secure the reliability of the semiconductor device, various types of electrostatic discharge protection structures including ESD protection diode, silicon controlled rectifier (SCR), and grounded gate NMOS (GGNMOS) device are being developed.

Recently, the integration degree of the semiconductor device has been further enhanced, and as a scheme for increasing efficiency of power supply, a BSPDN (Backside Power Delivery Network) structure is being adopted. Such a structure may require new design considerations in aspects such as arrangement method of the ESD protection circuit, current path, and grounding connection method as power is supplied from the rear surface of the chip. Accordingly, various types of electrostatic discharge protection circuits are continuously being reviewed in terms of compatibility with the BSPDN structure.

### SUMMARY

A semiconductor device according to embodiments includes a lower layer comprising a lower insulating layer and a semiconductor layer located on at least a portion of an upper surface of the lower insulating layer, a lower pattern located on the lower layer, the lower pattern comprising a first region comprising a semiconductor material and a second region located between the lower layer and the first region and comprising an insulating material, and a first collector pattern and a first emitter pattern located apart from one another along a first direction parallel to the upper surface of the lower layer, wherein the semiconductor layer and the first region constitute at least a portion of a body portion, and a first thickness of the body portion in a vertical direction under the first collector pattern is smaller than a second thickness of the body portion in the vertical direction under the first emitter pattern.

A semiconductor device according to embodiments includes a body portion, a first contact pattern located on an upper surface of the body portion, a second contact pattern located apart from the first contact pattern along a first direction and a plurality of collector-emitter pairs located between the first contact pattern and the second contact pattern and arranged along the first direction, wherein the first contact pattern and the second contact pattern are located at opposite ends of the body portion, the plurality of collector-emitter pairs each comprise a collector pattern and an emitter pattern located apart from one another along the first direction, and a thickness of the body portion in a vertical direction gradually decreases from a collector-emitter pair located in a middle of the plurality of collector-emitter pairs toward each of the first contact pattern and the second contact pattern.

A semiconductor device including a first unit cell region, a second unit cell region, and a third unit cell region arranged on a lower layer along a first direction parallel to an upper surface of the lower layer, wherein the semiconductor device comprise a lower pattern located on the lower layer and extending in the first direction, the lower pattern including a first region comprising a semiconductor material, and a second region located between the first region and the lower layer and comprising an insulating material, a first collector pattern, a first emitter pattern, a second collector pattern, a second emitter pattern, a third collector pattern, and a third emitter pattern sequentially spaced apart in the first direction, a first contact pattern located on the lower pattern and spaced apart from the first collector pattern in the first direction, a second contact pattern located on the lower pattern and spaced apart from the third emitter pattern in the first direction, intermediate insulating layers located between the collector patterns and the emitter patterns and including air gaps, an upper wiring structure located over the collector patterns, the emitter patterns, and the contact patterns, upper contact electrodes connecting each of the collector patterns, emitter patterns, and contact patterns to the upper wiring structure, wherein the first collector pattern is located between the first contact pattern and the first emitter pattern, the third emitter pattern is located between the third collector pattern and the second contact pattern, the first collector pattern and the first emitter pattern are included in the first unit cell region, the second collector pattern and the second emitter pattern are included in the second unit cell region, the third collector pattern and the third emitter pattern are included in the third unit cell region, the lower layer includes a lower insulating layer and a semiconductor layer located on at least a portion of an upper surface of the lower insulating layer, the semiconductor layer and the first region constitute at least a portion of a body portion, the thickness of the body portion in the vertical direction gradually increases toward the second unit cell region from the first contact pattern, the thickness of the body portion in the vertical direction gradually decreases away from the second unit cell region toward the second contact pattern.

According to embodiments, a semiconductor device having improved reliability may be provided.

### BRIEF DESCRIPTION OF THE DRAWINGS

FIG. 1 is a plan view showing a semiconductor device according to embodiments.

FIG. 2 is a cross-sectional view of the semiconductor device taken along the 11-11′ line of FIG. 1.

FIG. 3 is a cross-sectional view of the semiconductor device taken along line 12-12′ of FIG. 1.

FIG. 4 is a cross-sectional view of the semiconductor device taken along the 13-13′ line of FIG. 1.

FIG. 5 is a cross-sectional view of the semiconductor device taken along line 14-14′ of FIG. 1.

FIG. 6 is a drawing for describing the operation and effects of the ESD protection structure included in the semiconductor device according to embodiments.

FIG. 7 and FIG. 8 are drawings for illustrating a semiconductor device according to embodiments.

FIG. 9 is a drawing for explaining a semiconductor device according to embodiments.

FIG. 10 and FIG. 11 are drawings for explaining a semiconductor device according to embodiments.

FIG. 12 and FIG. 13 are drawings for explaining a semiconductor device according to embodiments.

FIG. 14 to FIG. 17 are drawings for describing a semiconductor device according to embodiments.

### DETAILED DESCRIPTION

Hereinafter, various embodiments of the present disclosure will be described in detail with reference to the accompanying drawings so that those skilled in the art to which the present disclosure pertains may easily implement the disclosure. The present disclosure may be implemented in various different forms and is not limited to the embodiments described herein.

In order to clearly describe the present disclosure, portions unrelated to the description have been omitted, and throughout the specification, identical reference numerals are assigned to identical or similar components.

In addition, the size and thickness of each component shown in the drawings are illustrated arbitrarily for the convenience of explanation, and thus the present disclosure is not necessarily limited to what is depicted. In the drawings, the thicknesses are enlarged to clearly illustrate the various layers and regions. In the drawings, for convenience of explanation, the thicknesses of some layers and regions are illustrated exaggeratedly.

Also, when a portion such as a layer, film, region, or plate is described as being “on” or “over” another portion, this includes not only the case where it is “directly on” the other portion, but also cases where another portion exists in between. Conversely, when it is stated that a portion is “directly on” another portion, it means that there is no other portion in between. In addition, stating that a portion is “on” or “above” a reference portion means that it is located above or below the reference portion, and does not necessarily mean that it is located “on” or “above” in a direction opposite to gravity.

In addition, throughout the entire specification, when a portion is described as including a certain component, this means that, unless specifically stated otherwise, it does not exclude other components and may further include other components.

In addition, throughout the entire specification, the term “in plan view” refers to viewing the target portion from above, and the term “in cross-sectional view” refers to viewing a cross-section of the target portion, which has been vertically cut, from the side.

Hereinafter, a semiconductor device according to embodiments will be described with reference to the drawings.

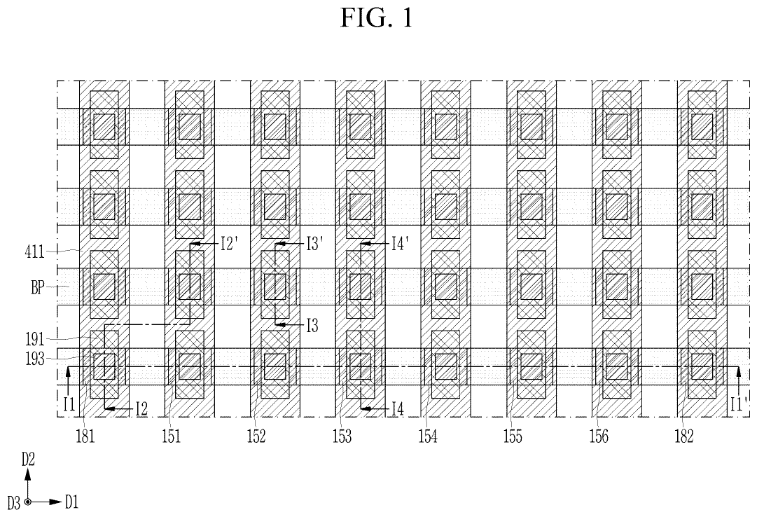

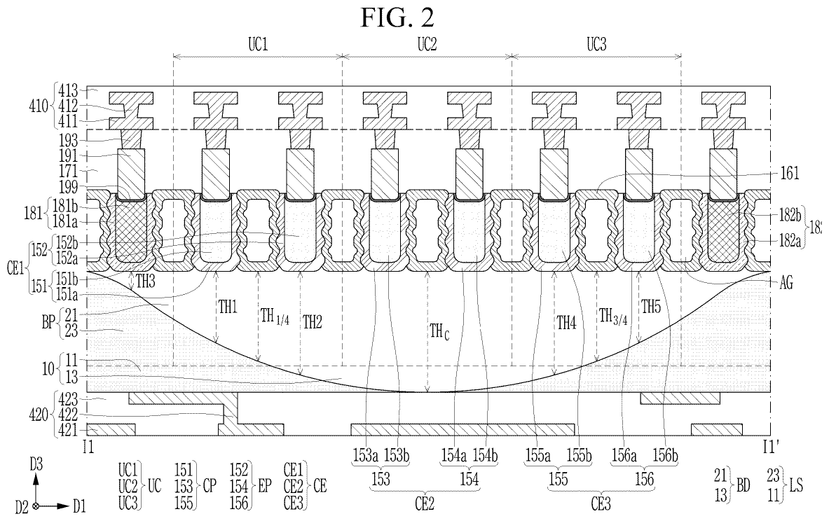

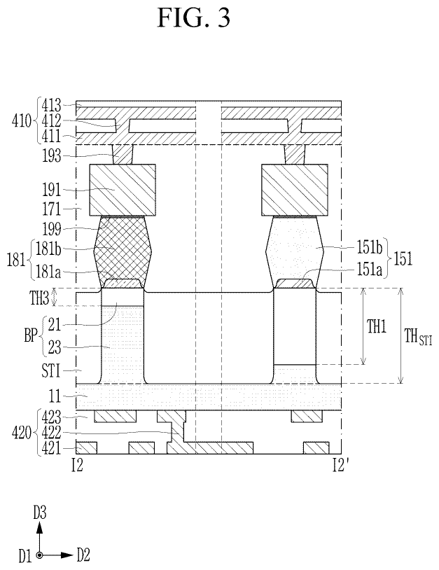

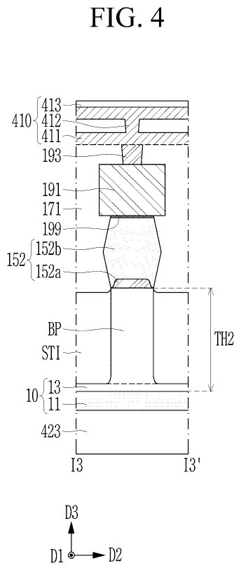

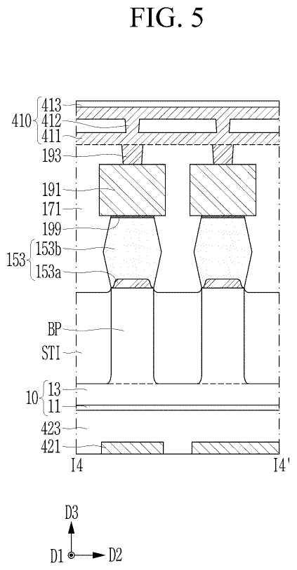

FIG. 1 is a plan view showing a semiconductor device according to embodiments, FIG. 2 is a cross-sectional view of the semiconductor device taken along line 11-11′ of FIG. 1, FIG. 3 is a cross-sectional view of the semiconductor device taken along line 12-12′ of FIG. 1, FIG. 4 is a cross-sectional view of the semiconductor device taken along line 13-13′ of FIG. 1, and FIG. 5 is a cross-sectional view of the semiconductor device taken along line 14-14′ of FIG. 1.

A semiconductor device according to the embodiments may include an electrostatic discharge (ESD) protection structure. The ESD protection structure may, for example, divert electrostatic 1discharge current that may flow into the semiconductor device to the outside, thereby preventing damage to the internal circuit. The ESD protection structure may provide a discharge path that releases an electrostatic discharge current, which may be introduced through an input terminal of the semiconductor device, to the outside before the electrostatic discharge current is delivered to an internal circuit of the semiconductor device.

In embodiments, the semiconductor device may include a GGNMOSFET (Grounded Gate NMOSFET) structure. However, it is not limited thereto, and the semiconductor device according to embodiments may include various types of ESD protection structure, such as a diode, a silicon controlled rectifier (SCR), or a clamping circuit including a plurality of transistors and wirings.

Referring to FIG. 1 to FIG. 5, a semiconductor device according to embodiments may include a lower layer 10, a lower pattern BP located on the lower layer 10, and collector patterns 151, 153, 155 and emitter patterns 152, 154, 156 located alternately on the lower pattern BP along the first direction D1.

A semiconductor device according to embodiments may include a first unit cell region UC1, a second unit cell region UC2, and a third unit cell region UC3 located along a first direction D1 parallel to an upper surface of a lower layer 10. Although three unit cell regions UC1, UC2, UC3 are shown in FIG. 2, the disclosure is not limited thereto, and the semiconductor device according to embodiments may include a greater number of unit cell regions UC.

For example, the semiconductor device according to embodiments may further include a plurality of unit cell regions UC arranged along the first direction D1 between the first unit cell region UC1 and the second unit cell region UC2. For example, the semiconductor device according to embodiments may further include a plurality of unit cell regions UC arranged along the first direction D1 between the second unit cell region UC2 and the third unit cell region UC3. For example, in embodiments, the semiconductor device may include about 300 unit cell regions UC arranged along a first direction D1; however, this is not limited thereto.

In embodiments, the first unit cell region UC1 may be the closest, among a plurality of unit cell regions UC arranged along the first direction D1, to a first contact pattern 181 to be described later. In embodiments, the second unit cell region UC2 may be located at the center among the plurality of unit cell regions UC arranged along the first direction D1. In embodiments, the third unit cell region UC3 may be the closest, among a plurality of unit cell regions UC arranged along the first direction D1, to a second contact pattern 182 to be described later.

Each of the unit cell regions UC1, UC2, UC3 may include a collector-emitter pair CE to be described below. The collector-emitter pair CE may include collector patterns 151, 153, 155, and emitter patterns 152, 154, 156. Referring to FIG. 1, it is shown that each of the unit cell regions UC1, UC2, UC3 includes one collector pattern CP and one emitter pattern EP, but is not limited thereto. For example, each of the unit cell regions UC1, UC2, UC3 may include two or more collector patterns CP and/or two or more emitter patterns EP.

The collector pattern CP and the emitter pattern EP included in one unit cell region UC, together with at least a portion of the lower pattern BP located thereunder and at least a portion of the lower layer 10, may constitute at least a portion of one parasitic BJT (bipolar junction transistor). Each of the parasitic BJTs included in the unit cell regions UC1, UC2, UC3 may perform, for example, an ESD protection function. This will be described in detail hereinafter.

The lower layer 10 may include a first surface and a second surface opposing the first surface. The first surface and the second surface of the lower layer 10 may be formed as planes parallel to a first direction D1 and a second direction D2 intersecting the first direction D1. For example, the first surface of the lower layer 10 may be the upper surface, and the second surface may be the lower surface. The upper surface of the lower layer 10 may be a surface of the lower layer 10 that is opposite to the lower surface of the lower layer 10 in the third direction D3. The third direction D3 may be perpendicular to the first direction D1 and the second direction D2. The lower surface of the lower layer 10 may be referred to as the back side of the lower layer 10.

In embodiments, the lower layer 10 may include two or more layers. Referring to FIG. 2, the lower layer 10 may include a lower insulating layer 11 and a semiconductor layer 13 located on a portion of the upper surface of the lower insulating layer 11.

The lower insulating layer 11 may be formed such that, in the process of manufacturing the semiconductor device according to embodiments, after the substrate is etched, the etched portion is filled with an insulating material, but is not limited thereto.

In embodiments, the thickness of the lower insulating layer 11 in the third direction D3 may not be uniform. In embodiments, a portion of the upper surface of the lower insulating layer 11 may have a concave shape in a direction toward the lower surface of the lower layer 10. In embodiments, a remaining portion of the upper surface of the lower insulating layer 11 may be flat. For example, referring to FIG. 2, the concave portion of the upper surface of the lower insulating layer 11 may be located at the middle portion of the entire region of the upper surface of the lower layer 10. In other words, the upper surface of the lower insulating layer 11 may be concave such that the middle portion is in a direction facing the lower surface of the lower layer 10, and both sides of the middle portion may have a flat shape. In embodiments, the concave portion of the upper surface of the lower insulating layer 11 may be filled by the semiconductor layer 13.

The lower insulating layer 11 may include an insulating material. For embodiment, the lower insulating layer 11 may include at least one selected from the group consisting of silicon nitride (SiNx), silicon oxynitride (SiON), silicon oxide (SiO₂), silicon oxycarbonitride (SiOCN), silicon boron nitride (SiBN), silicon oxyboronitride (SiOBN), silicon oxycarbide (SiOC), and combinations thereof.

The semiconductor layer 13 may be located on a portion of the lower insulating layer 11. The semiconductor layer 13 may be a remaining portion of the substrate that is not etched during a backside etching process for forming a BSPDN (Backside Power Delivery Network) structure in manufacturing the semiconductor device according to embodiments, but is not limited thereto.

The semiconductor layer 13 may fill the concave portion in the middle of the upper surface of the lower insulating layer 11. Referring to FIG. 2, the upper surface of the semiconductor layer 13 may be flat. The lower surface of the semiconductor layer 13 may have a convex shape toward the lower surface of the lower layer 10. Referring to FIG. 2, a thickness of the semiconductor layer 13 in the vertical direction may gradually increase from both ends of the semiconductor layer 13 toward a center thereof.

In embodiments, the semiconductor layer 13 may include semiconductor material. For example, the semiconductor layer 13 may include silicon (Si), but is not limited thereto. For example, the semiconductor layer 13 may include silicon germanium (SiGe), SGOI (silicon germanium on insulator), indium antimonide, lead telluride compound, indium arsenide, indium phosphide, gallium arsenide, or gallium antimonide.

In embodiments, the semiconductor layer 13 may be doped by an impurity. In embodiments, the semiconductor layer 13 may be doped with an impurity of the same type as that of at least a portion of the lower pattern BP, which will be described later. In embodiments, the semiconductor layer 13 may be doped with the same impurity as the contact patterns 181, 182, which will be described later. In embodiments, the semiconductor layer 13 may be doped by impurities of different types from the collector patterns 151, 153, 155 and the emitter patterns 152, 154, 156, which will be described later. For example, the semiconductor layer 13 may be doped by a P-type impurity. For example, when the semiconductor layer 13 includes silicon (Si), the semiconductor layer 13 may be doped by at least one of boron (B), gallium (Ga), and indium (In), but is not limited thereto.

The lower pattern BP may be located on the lower layer 10. A semiconductor device according to embodiments may include a plurality of lower patterns BP. The lower patterns BP may be portions protruded in the third direction D3 from the first surface of the lower layer 10. A shape protruding along the third direction D3 of the lower pattern BP may be formed, for example, during a FEOL (Front End Of Line) process step in the manufacturing process of a semiconductor device, by selectively etching a portion of the front surface of an epitaxial layer grown on the substrate.

The lower patterns BP may extend in the first direction D1. The lower patterns BP may be arranged spaced apart from one another along the second direction D2 on the first surface of the lower layer 10. Collector patterns 151, 153, 155, emitter patterns 152, 154, 156, and contact patterns 181, 182, which will be described later, may be located on the lower patterns BP. In embodiments, the collector patterns 151, 153, 155 and the emitter patterns 152, 154, 156 may be arranged alternately spaced apart along the first direction D1 on each lower pattern BP.

In the example, the lower pattern BP may include a first region 21 and a second region 23 located between the first region 21 and the lower layer 10. In embodiments, the first region 21 includes a semiconductor material, and the second region 23 may include an insulating material. In embodiments, the first region 21 and the second region 23 may be formed by etching a portion of the rear surface of the epitaxial layer formed on the substrate in a process for forming a BSPDN structure, and then filling it with insulating material, but are not limited thereto.

In embodiments, the first region 21 may include the same semiconductor material as the semiconductor layer 13. For example, the first region 21 may include silicon (Si), but is not limited thereto. For example, the first region 21 may include silicon germanium (SiGe), SGOI (silicon germanium on insulator), indium antimonide, lead telluride compound, indium arsenide, indium phosphide, gallium arsenide, or gallium antimonide.

In embodiments, the first region 21 may be doped by an impurity. In embodiments, the first region 21 may be doped by an impurity of the same type as the semiconductor layer 13. In embodiments, the first region 21 may be doped with the same impurity as the contact patterns 181, 182 to be described later. In embodiments, the first region 21 may be doped by impurities of different types from the collector patterns 151, 153, 155 and the emitter patterns 152, 154, 156, which will be described later. For example, the first region 21 may be doped with a P-type impurity. For example, when the first region 21 includes silicon (Si), the first region 21 may be doped with at least one of boron (B), gallium (Ga), and indium (In), but is not limited thereto.

In embodiments, the second region 23 may include the same insulating material as the lower insulating layer 11. For example, the second region 23 may include at least one selected from the group consisting of silicon nitride (SiNx), silicon oxynitride (SiON), silicon oxide (SiO₂), silicon oxycarbonitride (SiOCN), silicon boron nitride (SiBN), silicon oxyboronitride (SiOBN), silicon oxycarbide (SiOC), and combinations thereof.

In embodiments, the first region 21 may constitute a body portion BD together with the semiconductor layer 13. The body portion BD may constitute a parasitic BJT included in each of the unit cell regions UC1, UC2, UC3 together with the collector patterns 151, 153, 155 and the emitter patterns 152, 154, 156 to be described later. In embodiments, the body portion BD may function as a base region of the parasitic BJT included in each of the unit cell regions UC1, UC2, UC3.

The body portion BD may extend along the first direction D1. In embodiments, the thickness of the body portion BD in the third direction D3 may not be uniform. For example, referring to FIG. 2, the thickness of the body portion BD along the third direction D3 may gradually increase toward the middle portion along the first direction D1 from both ends of the body portion BD. In embodiments, the thickness of the body portion BD in a third direction D3 may gradually decrease from a collector-emitter pair CE located in the middle among the plurality of collector-emitter pairs CE to be described later, toward the first contact pattern 181 and the second contact pattern 182.

In embodiments, the second region 23 may constitute a lower insulating structure LS together with the lower insulating layer 11. The lower insulating structure LS may be located on the lower surface of the body portion BD. The lower insulating structure LS may cover the lower surface of the body portion BD. In the example, the thickness of the lower insulating structure LS in the third direction D3 may not be constant. For example, referring to FIG. 2, the thickness of the lower insulating structure LS in the third direction D3 may gradually decrease toward the middle portion along the first direction D1 from both ends of the lower insulating structure LS. In embodiments, the thickness of the lower insulating structure LS in the third direction D3 may gradually increase from the collector-emitter pair CE located in a middle among the plurality of collector-emitter pairs CE to be described later, toward a first contact pattern 181 and a second contact pattern 182.

A semiconductor device according to embodiments may further include a field insulating layer STI located on a lower layer 10. The field insulating layer STI may be located between two lower patterns BP adjacent to one another in the second direction D2. The field insulating layer STI may not be located on the upper surface of the lower pattern BP.

The field insulating layer STI may be located on the upper surface of the lower layer 10 and on side surfaces of the lower patterns BP. The field insulating layer STI may entirely cover the side surface of the lower pattern BP. Unlike what is illustrated, the field insulating layer STI may cover a portion of the side of the lower pattern BP. In this case, a portion of the lower pattern BP may protrude further in the third direction D3 than the upper surface of the field insulating layer STI.

The field insulating layer STI may, for example, include an oxide, a nitride, an oxynitride, or a composite layer thereof. The field insulating layer STI is illustrated as a single layer, but this is merely for convenience of explanation and is not limited thereto.

A semiconductor device according to an example may include a plurality of collector-emitter pairs CE arranged along a first direction D1 on an upper surface of a body portion BD (or a lower pattern BP). Referring to FIG. 2, the semiconductor device may include a first collector-emitter pair CE1, a second collector-emitter pair CE2, and a third collector-emitter pair CE3 arranged along the first direction D1. In embodiments, the number of collector-emitter pairs CE located on the body portion BD is not limited. For example, the semiconductor device according to embodiments may further include a plurality of collector-emitter pairs CE arranged along the first direction D1 between the first collector-emitter pair CE1 and the second collector-emitter pair CE2. For example, the semiconductor device according to embodiments may further include a plurality of collector-emitter pairs CE arranged along the first direction D1 between the second collector-emitter pair CE2 and the third collector-emitter pair CE3.

A plurality of collector-emitter pairs CE may each include at least one collector pattern CP and at least one emitter pattern EP. Referring to FIG. 2, the first collector-emitter pair CE1 may include the first collector pattern 151 and the first emitter pattern 152. The first collector pattern 151 and the first emitter pattern 152 may be located spaced apart from one another along the first direction D1. The first collector-emitter pair CE1 may be included in the first unit cell region UC1. In embodiments, the first collector pattern 151 and the first emitter pattern 152, together with a portion of the body portion BD located thereunder, may constitute at least a portion of the parasitic BJT of the first unit cell region UC1. In embodiments, the first collector-emitter pair CE1 may be located closest to the first contact pattern 181, which will be described later, among the plurality of collector-emitter pairs CE arranged along the first direction D1.

The second collector-emitter pair CE2 may include the second collector pattern 153 and the second emitter pattern 154. The second collector pattern 153 and the second emitter pattern 154 may be located spaced apart from one another along the first direction D1. The second collector-emitter pair CE2 may be included in the second unit cell region UC2. In embodiments, the second collector pattern 153 and the second emitter pattern 154, together with a portion of the body portion BD located thereunder, may constitute at least a portion of the parasitic BJT of the second unit cell region UC2.

In embodiments, the second collector-emitter pair CE2 may be located in the middle among the plurality of collector-emitter pairs CE arranged along the first direction D1. The distance in the first direction D1 between the second collector-emitter pair CE2 and the first contact pattern 181 may be substantially the same as the distance in the first direction D1 between the second collector-emitter pair CE2 and the second contact pattern 182. The distance in the first direction D1 between the second collector pattern 153 and the first contact pattern 181 may be substantially the same as the distance in the first direction D1 between the second emitter pattern 154 and the second contact pattern 182.

The third collector-emitter pair CE3 may include a third collector pattern 155 and a third emitter pattern 156. The third collector pattern 155 and the third emitter pattern 156 may be located spaced apart from one another along the first direction D1. The third collector-emitter pair CE3 may be included in the third unit cell region UC3. In embodiments, the third collector pattern 155 and the third emitter pattern 156 may constitute at least a portion of the parasitic BJT of the third unit cell region UC3 together with a portion of the body portion BD located therebelow. In embodiments, the third collector-emitter pair CE3 may be located most adjacent to the second contact pattern 182, which will be described later, among the plurality of collector-emitter pairs CE arranged along the first direction D1.

The collector patterns 151, 153, 155 and the emitter patterns 152, 154, 156 may be constituted by an epitaxial layer formed by a selective epitaxial growth (SEG) method. The collector patterns 151, 153, 155 and the emitter patterns 152, 154, 156 may be formed by removing at least a portion of a semiconductor pattern stacked on the lower pattern BP and then performing selective epitaxial growth in the removed region.

The collector patterns 151, 153, 155 and the emitter patterns 152, 154, 156 may each include a liner layer 151a, 152a, 153a, 154a, 155a, 156a and a filling layer 151b, 152b, 153b, 154b, 155b, 156b. With reference to FIG. 2 and FIG. 3, the collector patterns 151, 153, 155 and the emitter patterns 152, 154, 156 may each include a filling layer 151b, 152b, 153b, 154b, 155b, 156b and a liner layer 151a, 152a, 153a, 154a, 155a, 156a. The liner layer 151a, 152a, 153a, 154a, 155a, 156a may be located outside the filling layer 151b, 152b, 153b, 154b, 155b, 156b. The side surface and lower surface of the filling layer 151b, 152b, 153b, 154b, 155b, 156b may be surrounded by the liner layer 151a, 152a, 153a, 154a, 155a, 156a. The liner layer 151a, 152a, 153a, 154a, 155a, 156a may be in direct contact with the intermediate insulating layer 161, which will be described later. The filling layer 151b, 152b, 153b, 154b, 155b, 156b may be located on the liner layer 151a, 152a, 153a, 154a, 155a, 156a. The filling layers 151b, 152b, 153b, 154b, 155b, 156b and the liner layers 151a, 152a, 153a, 154a, 155a, 156a may have an upper surface of substantially the same height. However, it is not limited thereto, and, unlike that shown in FIG. 2, the filling layer 151b, 152b, 153b, 154b, 155b, 156b and the liner layer 151a, 152a, 153a, 154a, 155a, 156a may have upper surfaces of different heights in a portion.

The collector pattern CP and the emitter pattern EP may include a semiconductor material. In embodiments, the collector pattern CP and the emitter pattern EP may include semiconductor materials different from the contact patterns 181, 182 to be described later, but are not limited thereto. The collector pattern CP and emitter pattern EP may, for example, include silicon (Si) or germanium (Ge). In addition, the collector pattern CP and emitter pattern EP may include, for example, a binary compound including at least two or more of carbon (C), silicon (Si), germanium (Ge), and tin (Sn), or may include a ternary compound. For example, the collector pattern CP and the emitter pattern EP may include silicon (Si), silicon germanium (SiGe), germanium (Ge), silicon carbide (SIC), and the like, but are not limited thereto.

In embodiments, the collector patterns 151, 153, 155 and the emitter patterns 152, 154, 156 may include N-type dopants. For example, the collector patterns 151, 153, 155 and the emitter patterns 152, 154, 156 may be doped by the impurity. For example, when the collector patterns 151, 153, 155 and emitter patterns 152, 154, 156 are including silicon (Si) or silicon germanium (SiGe), the collector patterns 151, 153, 155 and emitter patterns 152, 154, 156 may be doped by at least one of phosphorus (P), arsenic (As), and antimony (Sb), but are not limited thereto. In embodiments, the collector patterns 151, 153, 155 and the emitter patterns 152, 154, 156 may be doped by dopants of types different from those of the body portion BD and the contact patterns 181, 182 to be described later.

In embodiments, the collector patterns 151, 153, 155 and the emitter patterns 152, 154, 156 may include P-type dopants. For example, the collector patterns 151, 153, 155 and the emitter patterns 152, 154, 156 each may be doped by a P-type impurity. For example, when the collector patterns 151, 153, 155 and the emitter patterns 152, 154, 156 include silicon (Si) or silicon germanium (SiGe), the collector patterns 151, 153, 155 and the emitter patterns 152, 154, 156 may be doped by at least one of boron (B), gallium (Ga), and indium (In); however, the present disclosure is not limited thereto.

A semiconductor device according to embodiments may further include a first contact pattern 181 and a second contact pattern 182 located on an upper surface of a body portion BD (or a lower pattern BP). In embodiments, the first contact pattern 181 may be located at one end of the upper surface of the body portion BD or the lower pattern BP. The second contact pattern 182 may be located at the other end of the upper surface of the body portion BD or the lower pattern BP.

Referring to FIG. 2, the first contact pattern 181 and the second contact pattern 182 may be located spaced apart from one another along the first direction D1. A plurality of collector-emitter pairs CE may be located along the first direction D1 between the first contact pattern 181 and the second contact pattern 182.

The first contact pattern 181 may be located apart, along a first direction D1, from either the collector pattern CP or the emitter pattern EP included in a collector-emitter pair CE which is closest among the plurality of collector-emitter pairs CE. Referring to FIG. 2, the first contact pattern 181 may be located spaced apart along the first direction D1 from the first collector pattern 151 included in the first collector-emitter pair CE1. An intermediate insulating layer 161 to be described later may be located between the first contact pattern 181 and the first collector pattern 151.

The second contact pattern 182 may be located apart, along a first direction D1, from either the collector pattern CP or the emitter pattern EP included in a collector-emitter pair CE which is closest among the plurality of collector-emitter pairs CE. Referring to FIG. 2, the second contact pattern 182 may be located spaced apart from the third emitter pattern 156 included in the third collector-emitter pair CE3 along the first direction D1. An intermediate insulating layer 161, to be described later, may be located between the second contact pattern 182 and the third emitter pattern 156.

The contact patterns 181, 182 may be in contact with the upper surface of the body portion BD or the lower pattern BP. In embodiments, the body portion BD may include the base region of the parasitic BJT, and each of the contact patterns 181, 182 may function as a path for current flow between the body portion BD and the upper contact electrode 191 to be described later. In embodiments, the contact patterns 181, 182 and the body portion BD may form an ohmic contact.

The contact patterns 181, 182 may be constituted by an epitaxial layer formed by a selective epitaxial growth (SEG) method. The contact patterns 181, 182 may be formed by removing at least a portion of a semiconductor pattern stacked on the lower pattern BP and then performing selective epitaxial growth in the removed region.

The contact patterns 181, 182 may each include a liner layer 181a, 182a and a filling layer 181b, 182b. Referring to FIG. 2 and FIG. 3, the contact patterns 181 and 182 may respectively include the filling layers 181b and 182b and the liner layers 181a and 182a. The filling layer 181b, 182b and the liner layer 181a, 182a are identical to the filling layer 151b, 152b, 153b, 154b, 155b, 156b and the liner layer 151a, 152a, 153a, 154a, 155a, 156a of the collector pattern CP and the emitter pattern EP, and thus, a detailed description thereof will be omitted.

The contact patterns 181, 182 may include a semiconductor material. In embodiments, the contact patterns 181, 182 may include a semiconductor material different from that of the collector pattern CP and the emitter pattern EP, but are not limited thereto. The contact patterns 181, 182 may include, for example, silicon (Si) or germanium (Ge). In addition, the contact patterns 181, 182 may include a binary compound including at least two or more of carbon (C), silicon (Si), germanium (Ge), and tin (Sn), or may include a ternary compound. For example, the contact patterns 181, 182 may include silicon (Si), silicon germanium (SiGe), germanium (Ge), silicon carbide (SIC), and the like, but are not limited thereto.

In embodiments, the contact patterns 181, 182 may include P-type dopants. For example, the contact patterns 181, 182 may be doped by an impurity. For example, when the contact patterns 181, 182 include silicon (Si) or silicon germanium (SiGe), the contact patterns 181, 182 may be doped by at least one selected from the group consisting of phosphorus (P), arsenic (As), and antimony (Sb), but are not limited thereto. In embodiments, the contact patterns 181, 182 may be doped by a dopant of the same type as the body portion BD. In this case, the doping concentration of the contact patterns 181, 182 may be higher than the doping concentration of the body portion BD.

In embodiments, the contact patterns 181, 182 may be doped with a dopant of a different conductivity type from that of the collector pattern CP and the emitter pattern EP.

In embodiments, the contact patterns 181, 182 may include N-type dopants. For example, each of the contact patterns 181, 182 may be doped by an N-type impurity. For example, when the contact patterns 181, 182 include silicon (Si) or silicon germanium (SiGe), the contact patterns 181, 182 may be doped by at least one of phosphorus (P), arsenic (As), and antimony (Sb), but are not limited thereto.

In embodiments, the thickness in the third direction D3 of the body portion BD located below contact patterns 181, 182 and the plurality of collector-emitter pairs CE arranged along the first direction D1 may not be constant.

Referring to FIG. 2, between the first contact pattern 181 and the second unit cell region UC2, the thickness of the body portion BD in a third direction D3 may gradually increase toward the second unit cell region UC2 along the first direction D1 from the first contact pattern 181. In embodiments, between the first contact pattern 181 and the second unit cell region UC2, the thickness of the first region 21 in the third direction D3 may include a portion that gradually increases toward the second unit cell region UC2 along the first direction D1 from the first contact pattern 181.

In embodiments, the average thickness of the body portion BD in the first unit cell region UC1 in the third direction D3 may be smaller than the average thickness of the body portion BD in the second unit cell region UC2 in the third direction D3. In embodiments, the average thickness of the body portion BD in the second unit cell region UC2 in the third direction D3 may be greater than the average thickness of the body portion BD in the third unit cell region UC3 in the third direction D3.

Referring to FIG. 2 to FIG. 4, in embodiments, the first thickness TH1 in the third direction D3 (that is, substantially perpendicular to the upper surface of the lower layer (10)) of the body portion BD located below the first collector pattern 151 (that is, between the first collector pattern 151 and the lower insulating structure LS) may be less than the second thickness TH2 in the third direction D3 of the body portion BD located below the first emitter pattern 152 (that is, between the first emitter pattern 152 and the lower insulating structure LS).

With reference to FIG. 2 and FIG. 3, in embodiments, a third thickness TH3 of the body portion BD located under the first contact pattern 181 (that is, between the first contact pattern 181 and the lower insulating structure LS) in the third direction D3 may be less than a first thickness TH1 of the body portion BD located under the first collector pattern 151 (that is, between the first collector pattern 151 and the lower insulating structure LS) in the third direction D3.

Referring to FIG. 3, in embodiments, the ratio of the third thickness TH3 of the body portion BD to the thickness TH_{STI} of the field insulating layer STI in the third direction D3 may be greater than or equal to about 0.2, and may be less than or equal to about 0.25.

Referring to FIG. 2, between the second unit cell region UC2 and the second contact pattern 182, a thickness of the body portion BD in a third direction D3 may gradually decrease toward the second contact pattern 182 along a first direction D1 from the second unit cell region UC2. In embodiments, between the second unit cell region UC2 and the second contact pattern 182, the thickness of the first region 21 in the third direction D3 may include a portion that gradually decreases toward the second contact pattern 182 along the first direction D1 from the second unit cell region UC2.

Referring to FIG. 2, in embodiments, a fourth thickness TH4 in the third direction D3 of a body portion BD located below the third collector pattern 155 (that is, between the third collector pattern 155 and the lower insulating structure LS) may be greater than a fifth thickness TH5 in the third direction D3 of the body portion BD located below the third emitter pattern 156 (that is, between the third emitter pattern 156 and the lower insulating structure LS).

In embodiments, the thickness of the body portion BD in the third direction D3 may be greatest at a middle point of an entire length of the body portion BD extending along the first direction D1. Referring to FIG. 2 and FIG. 3, the ratio of the thickness TH_{C} at the middle point of the entire length of the body portion BD with respect to the thickness TH_{STI} of the field insulating layer STI in the third direction D3 may be greater than or equal to about 1.2 and less than or equal to 2.5.

Referring to FIG. 2 and FIG. 3, the ratio of the thickness TH_{1/4} of the body portion BD at about a one-quarter point of the entire length of the body portion BD extending along the first direction D1 to the thickness TH_{STI} of the field insulating layer STI in the third direction D3 may be greater than or equal to about 0.95 and less than or equal to about 1.05. In FIG. 2, the one-quarter point of the entire length of the body portion BD is illustrated as being located between the first collector pattern 151 and the first emitter pattern 152. However, this is for convenience of description, and depending on the number of all unit cell regions UC arranged along the first direction D1 on the body portion BD, one-quarter point of the entire length of the body portion BD may be located not between the first collector pattern 151 and the first emitter pattern 152, but elsewhere.

Referring to FIG. 2 and FIG. 3, the ratio of the thickness TH_{3/4} of the body portion BD at about a three-quarter point of the entire length of the body portion BD extending along the first direction D1 to the thickness TH_{STI} of the field insulating layer STI in the third direction D3 may be greater than or equal to about 0.95 and less than or equal to about 1.05. In FIG. 2, the three-quarter point of an entire length of the body portion BD is illustrated as being located between the third collector pattern 155 and the third emitter pattern 156. However, this is for the convenience of explanation, and depending on the number of all unit cell regions UC arranged on the body portion BD along the first direction D1, the three-quarter point of an entire length of the body portion BD may be located at a place other than between the third collector pattern 155 and the third emitter pattern 156.

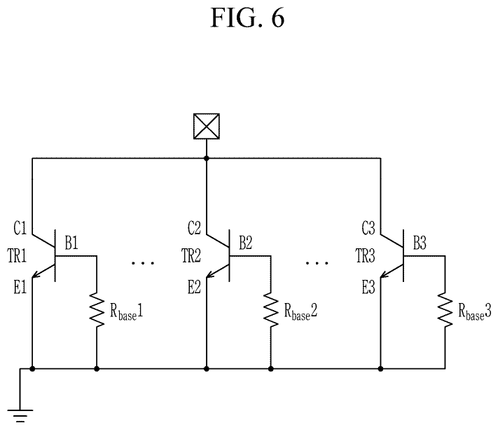

FIG. 6 is a drawing for explaining the operation and effect of the ESD protection structure included in the semiconductor device according to embodiments.

FIG. 6 may be a circuit diagram corresponding to at least a portion of the ESD protection structure described with reference to FIG. 1 to FIG. 5. In FIG. 6, the first transistor TR1 may be a parasitic BJT of the first unit cell region UC1 of FIG. 2. The first transistor TR1 may include a first collector C1, a first emitter E1, and a first base B1. A first base resistance R_{base}1 may be located between the first base B1 and ground. The first collector C1 and the first emitter E1 may respectively correspond to the first collector pattern 151 and the first emitter pattern 152 of FIG. 2. The first base B1 may correspond to a portion of the body portion BD located in the first unit cell region UC1 of FIG. 2. The first base resistance R_{base}1 may correspond to a portion of the body portion BD between the first collector-emitter pair CE1 and the first contact pattern 181.

The second transistor TR2 may be a parasitic BJT of the second unit cell region UC2 of FIG. 2. The second transistor TR2 may include a second collector C2, a second emitter E2, and a second base B2. A second base resistance R_{base}2 may be located between the second base B2 and ground. The second collector C2 and the second emitter E2 may respectively correspond to the second collector pattern 153 and the second emitter pattern 154 of FIG. 2. The second base B2 may correspond to a portion of the body portion BD located in the second unit cell region UC2 of FIG. 2. The second base resistance R_{base}2 may correspond to a portion of the body portion BD between the second collector-emitter pair CE2 and the first contact pattern 181, or to a portion of the body portion BD between the second collector-emitter pair CE2 and the second contact pattern 182.

The third transistor TR3 may be the parasitic BJT of the third unit cell region UC3 of FIG. 2. The third transistor TR3 may include a third collector C3, a third emitter E3, and a third base B3. A third base resistor R_{base}3 may be located between the third base B3 and ground. The third collector C3 and the third emitter E3 may each correspond to the third collector pattern 155 and the third emitter pattern 156 of FIG. 2. The third base B3 may correspond to a portion of the body portion BD located in the third unit cell region UC3 of FIG. 2. The third base resistor R_{base}3 may correspond to a portion of the body portion BD between the third collector-emitter pair CE3 and the second contact pattern 182.

Referring to FIG. 6, the first transistor TR1, the second transistor TR2, and the third transistor TR3 may be connected in parallel between an input power source and ground. In FIG. 6, only three transistors TR1, TR2, TR3 are illustrated; however, the present disclosure is not limited thereto, and the semiconductor device according to embodiments may include four or more transistors connected in parallel between the input terminal and ground. Referring to FIG. 6, the first collector C1, the second collector C2, and the third collector C3 are connected to the input terminal, and the first emitter E1, the second emitter E2, and the third emitter E3 may be connected to ground.

In embodiments, when an overcurrent is introduced into the input terminal by electrostatic discharge ESD, the overcurrent may be discharged to ground through a plurality of transistors TR1, TR2, TR3. Specifically, when a high voltage is applied to the input terminal by ESD, the PN junction between the collector C1, C2, C3 and the base B1, B2, B3 may be reverse-biased. At this time, when the applied voltage exceeds the breakdown voltage, holes may be injected from the collector C1, C2, C3 to the base B1, B2, B3. In this case, a plurality of transistors TR1, TR2, TR3 may be turned on, and the overcurrent may be discharged toward ground through the emitters E1, E2, E3.

As shown in FIG. 6, when the plurality of parasitic BJTs are connected in parallel between the input terminal and ground, the current may be distributed non-uniformly according to the difference in the β value (current gain) of each transistor TR1, TR2, TR3.

For example, the β value may be defined as follows.

B=I_{C}/I_{B} (I_{C} is collector current, I_{B} is base current) [Mathematical Formula 1]

And, considering that resistance is inversely proportional to current, the β value may be expressed as follows.

B∝R_{base}/R_{collector} (R_{base} is base resistance, R_{collector} is collector resistance) [Mathematical Formula 2]

With reference to [Mathematical Formula 2], when the collector resistance R_{collector} is constant, the higher the base resistance R_{base} of the parasitic BJT, a higher β value may be obtained, and accordingly, more current may flow through the parasitic BJT.

Referring to FIG. 2 and FIG. 6 together, in the semiconductor device according to embodiments, the base resistance R_{base} may be determined by the portion of the body portion BD located between the collector-emitter pair CE included in each of the unit cell regions UC1, UC2, UC3 and the contact patterns 181, 182. For example, the longer the length of a portion of the body portion BD located between the collector-emitter pair CE and the contact patterns 181, 182 in the first direction D1, the greater the base resistance R_{base} may be. For example, the thicker the thickness, in the third direction D3, of a portion of the body portion BD located between the collector-emitter pair CE and the contact patterns 181, 182, the smaller the base resistance R_{base} may be.

Referring to FIG. 2, among the plurality of collector-emitter pairs CE, the length of a portion of the body portion BD located between the second collector-emitter pair CE2 and the contact patterns 181, 182 in the first direction D1 may be the longest. In embodiments, the thickness of the body portion BD in the third direction D3 may be thinnest in the portion of the body portion BD located between the first collector-emitter pair CE1 and the first contact pattern 181, and between the third collector-emitter pair CE3 and the second contact pattern 182.

Unlike what is illustrated in FIG. 2, in the case where the thickness of the body portion BD along a third direction D3 is constant along a first direction D1, among the plurality of unit cell regions UC1, UC2, UC3 arranged in the first direction D1, the resistance value of the second base resistance R_{base}2 of the parasitic BJT (second transistor TR2 of FIG. 6) included in the centrally located second unit cell region UC2 may be excessively greater than the other resistances for example, the first base resistance (R_{base}1 or the third base resistor R_{base}3) (that is, R_{base}2>>R_{base}1, R_{base}3). In this case, due to a difference in β values resulting from the difference in resistance values of the base resistance R_{base}, current may be concentrated in a parasitic BJT included in the second unit cell region UC2 (the second transistor TR2 of FIG. 6) when an overcurrent caused by ESD is introduced. Accordingly, at least a portion of the ESD protection structure may be destroyed (break down) or deteriorated, and the reliability of the semiconductor device may be degraded.

According to embodiments, the thickness of the body portion BD in the third direction D3 may gradually decrease from the collector-emitter pair CE located in the middle of the plurality of collector-emitter pairs CE toward the first contact pattern 181 and the second contact pattern 182. In this case, the resistance values of the first base resistance R_{base}1 and the second base resistance R_{base}2 may increase compared to the case where the thickness of the body portion BD in the third direction D3 is uniform along the first direction D1. Accordingly, the difference in β values between a parasitic BJT included in a unit cell region UC located in a middle among unit cell regions UC arranged along a first direction D1 and parasitic BJTs included in unit cell regions UC located at opposite ends may be partially offset.

According to embodiments, compared to the case in which the thickness of the body portion BD in a third direction D3 is constant along the first direction D1, an overcurrent introduced through the input terminal may be more evenly distributed and discharged among the plurality of parasitic BJTs, thereby improving the reliability of the semiconductor device according to embodiments.

Referring again to FIG. 1 to FIG. 5, the semiconductor device according to embodiments may further include an intermediate insulating layer 161 located between the collector patterns 151, 153, 155 and the emitter patterns 152, 154, 156. The intermediate insulating layer 161 may electrically separate the collector patterns 151, 153, 155 and the emitter patterns 152, 154, 156. The intermediate insulating layer 161 may be further located between the first contact pattern 181 and the first collector pattern 151, and between the second contact pattern 182 and the third emitter pattern 156.

The intermediate insulating layer 161 may be located on the body portion BD (or lower pattern BP). The lower surface of the intermediate insulating layer 161 may be in contact with the lower surface of the body portion BD. Referring to FIG. 2, the upper surface of the intermediate insulating layer 161 is shown as protruding further in the third direction D3 than the upper surfaces of the collector patterns 151, 153, 155, the emitter patterns 152, 154, 156, and the contact patterns 181, 182, but is not limited thereto.

The intermediate insulating layer 161 may include an insulating material. For example, the intermediate insulating layer 161 may include at least one selected from silicon nitride (SiNx), silicon oxynitride (SiON), silicon oxide (SiO₂), silicon oxycarbonitride (SiOCN), silicon boron nitride (SiBN), silicon oxyboronitride (SiOBN), silicon oxycarbide (SiOC), and combinations thereof.

In embodiments, the intermediate insulating layer 161 may include an air gap AG. The air gap AG may refer to an empty space located between one layer and another layer. In embodiments, the air gap AG may be filled with air; however, it is not limited thereto. For example, the air gap AG may include air or gas used in a semiconductor device manufacturing process, or may be in a vacuum state.

A semiconductor device according to embodiments may further include an interlayer insulating layer 171 covering contact patterns 181, 182, collector patterns 151, 153, 155, emitter patterns 152, 154, 156, and intermediate insulating layers 161.

The interlayer insulating layer 171 may be located on at least a portion of the upper surface of the contact patterns 181, 182, the collector patterns CP, the emitter patterns EP, and the intermediate insulating layers 161. Referring to FIG. 3 to FIG. 5, the interlayer insulating layer 171 may be located on the side surfaces of the contact patterns 181 and 182, the collector patterns CP, and the emitter patterns EP. Referring to FIG. 2 and FIG. 3, the interlayer insulating layer 171 may cover portion of the upper surface and the entire region of the side surface of the contact patterns 181, 182, the collector patterns CP, and the emitter patterns EP in a region not overlapping with the intermediate insulating layers 161 in the third direction D3. The interlayer insulating layer 171 may be further located on the upper surface of the field insulating layer STI.

The interlayer insulating layer 171 may include, for example, at least one of silicon oxide (SiO₂), silicon nitride (SiNx), silicon oxynitride (SiON), and a low dielectric constant material. The low dielectric constant material may include, for example, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyClo TetraSiloxane (OMCTS), HexaMethylDiSiloxane (HMDS), TriMethylSilyl Borate (TMSB), DiAcetoxyDitertiary ButoSiloxane (DADBS), TriMethylSilil Phosphate (TMSP), PolyTetraFluoroEthylene (PTFE), polyimide nanofoams such as TOSZ (Tonen SilaZen), FSG (Fluoride Silicate Glass), polypropylene oxide, CDO (Carbon Doped silicon Oxide), OSG (Organo Silicate Glass), SILK, Amorphous Fluorinated Carbon, silica aerogels, silica xerogels, mesoporous silica, or combinations thereof, but is not limited thereto.

In embodiments, the interlayer insulating layer 171 and the field insulating layer STI may include different insulating materials. However, this is not limited thereto, and in embodiments, the interlayer insulating layer 171 and the field insulating layer STI may include the same insulating material. In this case, a boundary between the interlayer insulating layer 171 and the field insulating layer STI may not be visually distinguishable.

The semiconductor device according to the Ex4ample may further include an upper contact electrode 191. The upper contact electrode 191 may be located on each of the contact patterns 181, 182, the collector patterns CP, and the emitter patterns EP. The upper contact electrode 191 may extend along the third direction D3 into the contact patterns 181, 182, the collector patterns CP, and the emitter patterns EP to a predetermined depth. The upper contact electrode 191 may not overlap the intermediate insulating layer 161 in the third direction D3. The upper contact electrode 191 may have an inclined side surface such that a lower width is narrower than an upper width according to an aspect ratio. For example, the width of the upper contact electrode 191 in a horizontal direction may have a shape that gradually narrows toward upper surfaces of the contact patterns 181, 182, the collector patterns CP, and the emitter patterns EP, respectively.

In embodiments, the upper contact electrode 191 may electrically connect the contact patterns 181, 182, the collector patterns CP, and the emitter patterns EP, and the upper wiring structure 410 to be described later.

The upper contact electrode 191 may have at least a portion surrounded by the interlayer insulating layer 171. Referring to FIG. 2 and FIG. 3 to FIG. 5, a portion of the upper surface and side surface of the upper contact electrode 191 may be covered by the interlayer insulating layer 171.

A semiconductor device according to embodiments may further include a silicide layer 199 located between contact patterns 181, 182, collector patterns CP, and emitter patterns EP and an upper contact electrode 191. In some embodiments, the semiconductor device may not include a silicide layer 199. In this case, unlike in FIG. 2 to FIG. 5, at least a portion of the side surface and at least a portion of the lower surface of the upper contact electrode 191 may be in contact with the contact patterns 181, 182, the collector patterns CP, and the emitter patterns EP.

A semiconductor device according to embodiments may further include an upper contact via 193 located on the upper contact electrode 191. The upper contact via 193, together with the upper contact electrode 191, may connect the contact patterns 181, 182, the collector patterns CP, and the emitter patterns EP to an upper wiring structure 410 to be described later.

The upper contact via 193 may contact at least a portion of the upper surface of the upper contact electrode 191. The upper contact via 193 may have side surfaces surrounded by the interlayer insulating layer 171.

The upper contact electrode 191 and the upper contact via 193 may include a conductive material. For example, the upper contact electrode 191 and the upper contact via 193 may include at least one of a metal, a metal alloy, a conductive metal nitride, a metal silicide, a doped semiconductor material, a conductive metal oxide, and a conductive metal oxynitride.

The semiconductor device according to embodiments may further include an upper wiring structure 410 located on an interlayer insulating layer 171. The upper wiring structure 410 may interconnect the contact patterns 181, 182, the collector patterns CP, and the emitter patterns EP, or may provide a path through which electrical signals such as voltage and current flow with respect to these. The upper wiring structure 410 may include at least a portion of the FSPDN (Front side power delivery network), but is not limited thereto.

The lower surface of the upper wiring structure 410 may contact a portion of the upper surface of the upper contact via 193. The upper wiring structure 410 may include upper wirings 411, upper wiring vias 412, and an upper wiring insulating layer 413. A plurality of upper wirings 411 may be arranged spaced apart from one another along the first direction D1. A plurality of upper wirings 411 may be spaced apart and located along the third direction D3. The upper wiring vias 412 may connect two upper wirings 411 located spaced apart from one another along the third direction D3. The upper wiring insulating layer 413 may surround the upper wirings 411 and the upper wiring vias 412. The upper wiring 411 and the upper wiring via 412 may be located in the upper wiring insulating layer 413.

The upper wiring 411 and the upper wiring via 412 may include a metal (for example, copper). The upper wiring insulating layer 413 may include at least one of silicon oxide (SiO₂), silicon nitride (SiNx), silicon oxynitride (SiON), or low dielectric constant layers.

In embodiments, the upper wiring 411 may include a portion extending along the second direction D2. Referring to FIG. 1 to FIG. 5, the upper wiring 411 may connect the first contact patterns 181, which are located spaced apart from one another along the second direction D2. The upper wiring 411 may connect the second contact patterns 182, which are spaced apart and located along the second direction D2, to one another. The upper wiring 411 may connect the first collector patterns 151, the first emitter patterns 152, the second collector patterns 153, the second emitter patterns 154, the third collector patterns 155, and the third emitter patterns 156 that are spaced apart and located along the second direction D2.

Although not clearly illustrated in FIG. 1 to FIG. 5, the upper wiring 411 connected to the first collector patterns 151, the upper wiring 411 connected to the second collector patterns 153, and the upper wiring 411 connected to the third collector patterns 155 may be electrically connected to one another. In embodiments, the upper wiring 411 connected to the first collector patterns 151, the upper wiring 411 connected to the second collector patterns 153, and the upper wiring 411 connected to the third collector patterns 155 may be connected to the input terminal, but are not limited thereto.

In embodiments, the upper wiring 411 connected to the first emitter patterns 152, the upper wiring 411 connected to the second emitter patterns 154, and the upper wiring 411 connected to the third emitter patterns 156 may be electrically connected to one another. In embodiments, the upper wiring 411 connected to the first emitter patterns 152, the upper wiring 411 connected to the second emitter patterns 154, and the upper wiring 411 connected to the third emitter patterns 156 may be connected to ground, but are not limited thereto.

In embodiments, the upper wiring 411 connected to the first contact patterns 181 and the upper wiring 411 connected to the second contact patterns 182 may be electrically connected to one another. In embodiments, the upper wiring 411 connected to the first contact patterns 181 and the upper wiring 411 connected to the second contact patterns 182 may be connected to ground, but are not limited thereto.

A semiconductor device according to embodiments may further include a lower wiring structure 420 located on a lower surface of a lower layer 10. The lower wiring structure 420 may be for providing power to other transistor structures located adjacent to the ESD protection structure described with reference to FIG. 1 to FIG. 5. The transistor structure may include, for example, a GAA (Gate All Around) including a nanowire or nanosheet, an MBCFET™ (Multi-Bridge Channel Field Effect Transistor) fin-type transistor (FinFET), a tunneling transistor (tunneling FET), a 3D-SFET (3D Stack Field Effect Transistor) structure, or a CFET (Complementary Field Effect Transistor) structure, but is not limited thereto. For example, the lower wiring structure 420 may include at least a portion of the BSPDN (Back side power delivery network).

The upper surface of the lower wiring structure 420 may contact the lower layer 10. The lower wiring structure 420 may include a lower wiring 421, a lower wiring via 422, and a lower wiring insulating layer 423. The lower wiring 421 may be located spaced apart from one another along the first direction D1, or may be located spaced apart from one another along the third direction D3. The lower wiring vias 422 may connect two lower wirings 421 that are spaced apart from one another and located along the third direction D3. The lower wiring insulating layer 423 may surround the lower wiring 421 and the lower wiring vias 422. The lower wirings 421 and the lower wiring vias 422 may be located in the lower wiring insulating layer 423.

The lower wiring 421 and the lower wiring via 422 may include a metal (for example, copper). The lower wiring insulating layer 423 may include at least one of silicon oxide (SiO₂), silicon nitride (SiNx), silicon oxynitride (SiON), or low dielectric constant layers, for example.

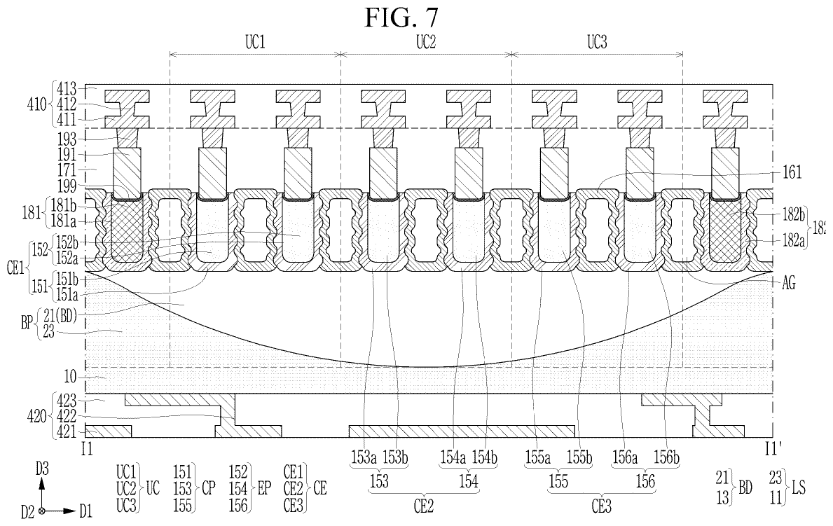

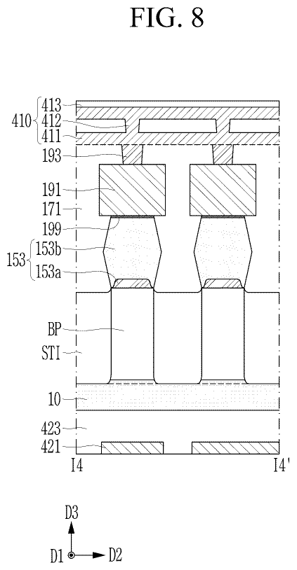

FIG. 7 and FIG. 8 are drawings for explaining a semiconductor device according to embodiments. Specifically, FIG. 7 is a cross-sectional view of the semiconductor device taken along the line 11-11′ of FIG. 1, and FIG. 8 is a cross-sectional view of the semiconductor device taken along the line 14-14′ of FIG. 1. The semiconductor device illustrated in FIG. 7 and FIG. 8 is substantially the same as the above-described embodiments with respect to the same portions; therefore, the following description focuses on the differences from the previous embodiments. The semiconductor device illustrated in FIG. 7 and FIG. 8 may have a thickness of the body portion BD that is partially different from that in the previous embodiments.

In embodiments, the body portion BD may be located on the lower layer 10. In contrast to the semiconductor device described with reference to FIG. 1 to FIG. 5, in which the body portion BD includes the first region 21 and the semiconductor layer 13, the body portion BD in embodiments may not include the semiconductor layer 13. In embodiments, the body portion BD may include the first region 21 of the lower pattern BP.

Referring to FIG. 7 and FIG. 8, the thickness of the body portion BD in the third direction D3 may gradually increase toward the second unit cell region UC2 along the first direction D1 from the first contact pattern 181. Between the second unit cell region UC2 and the second contact pattern 182, the thickness of the body portion BD in the third direction D3 may gradually decrease toward the second contact pattern 182 along the first direction D1 from the second unit cell region UC2. At this time, the level at which the lower surface of the body portion BD is located may be the same as the level at which the upper surface of the lower layer 10 is located, or may be slightly higher.

In embodiments, the thickness of the body portion BD in the third direction D3 may be greatest at a middle point of an entire length of the body portion BD extending along a first direction D1. In embodiments, the thickness of the body portion BD in the third direction D3 at the midpoint of the overall length of the body portion BD may be substantially the same as the maximum thickness of the field insulating layer STI in the third direction D3.

In embodiments, the lower layer 10 may not include the semiconductor layer 13 described with reference to FIG. 1 to FIG. 5.

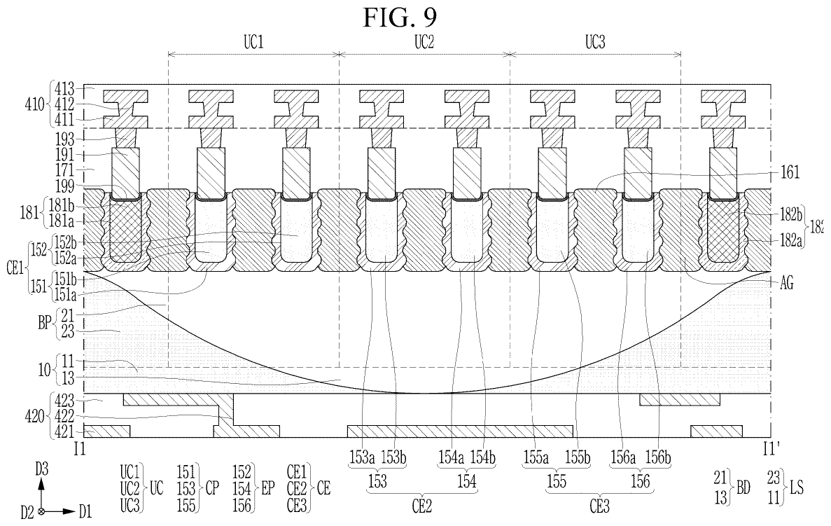

FIG. 9 is a drawing for illustrating a semiconductor device according to embodiments. Specifically, FIG. 9 is a cross-sectional view of the semiconductor device taken along the line 11-11′ of FIG. 1. The semiconductor device shown in FIG. 9 is substantially the same as the previous embodiments with respect to identical portions, and thus, hereinafter, differences from the previous embodiments will be mainly described.

In the semiconductor device according to embodiments, the intermediate insulating layers 161 may not include an air gap AG (see FIG. 2) therein. Referring to FIG. 9, the interiors of the intermediate insulating layers 161 may be filled with insulating material. The intermediate insulating layer 161 may include an insulating material. The intermediate insulating layer 161 may, for example, not include air or gases used in the semiconductor device manufacturing process therein. For example, the intermediate insulating layer 161 may include at least one selected from the group consisting of silicon nitride (SiNx), silicon oxynitride (SiON), silicon oxide (SiO₂), silicon oxycarbonitride (SiOCN), silicon boron nitride (SiBN), silicon oxyboronitride (SiOBN), silicon oxycarbide (SiOC), and combinations thereof.

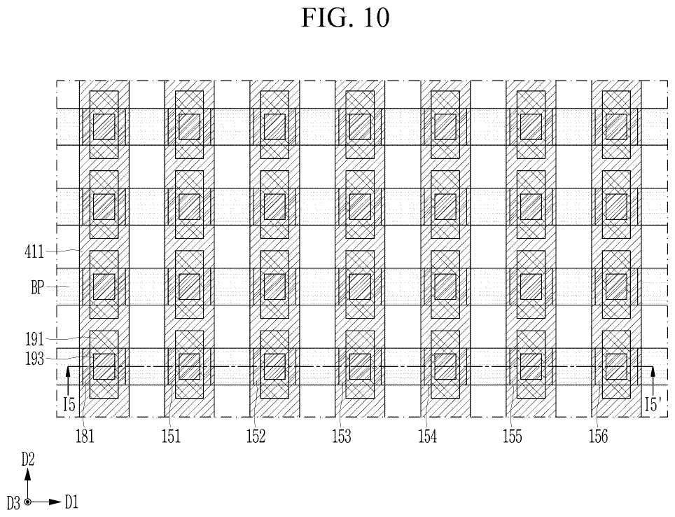

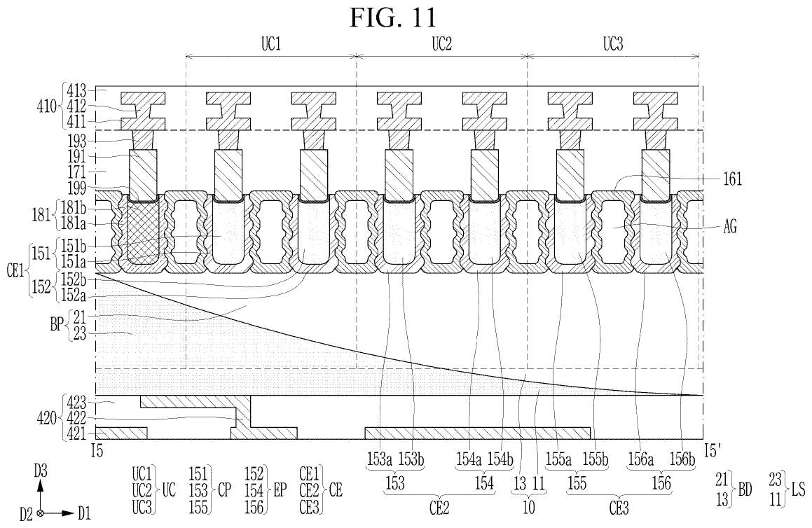

FIG. 10 and FIG. 11 are drawings for explaining a semiconductor device according to embodiments. Specifically, FIG. 10 is a plan view showing a semiconductor device according to embodiments, and FIG. 11 is a cross-sectional view of the semiconductor device taken along line 15-15′ of FIG. 10. The semiconductor device shown in FIG. 10 and FIG. 11 is substantially the same in portions as the previous embodiments, and therefore, the following description will focus on the differences from the previous embodiments. The semiconductor device illustrated in FIG. 10 and FIG. 11 may be partially different from the previous embodiments in that it does not include the second contact pattern 182 (see FIG. 2).

With reference to FIG. 10 and FIG. 11, a semiconductor device according to embodiments may include a first contact pattern 181 located at one end of an upper surface of a body portion BD extended along a first direction D1. In embodiments, at the other end of the upper surface of the body portion BD, a contact pattern may not be located.

In embodiments, the thickness of the body portion BD in the third direction D3 may gradually increase toward the third unit cell region UC3 along a first direction D1 from the first contact pattern 181. In embodiments, among the unit cell regions UC1, UC2, UC3 arranged along the first direction D1 on the body portion BD, the thickness of the body portion BD in the third direction D3 may be greatest in the third unit cell region UC3, which is farthest from the first contact pattern 181. In embodiments, among the unit cell regions UC1, UC2, UC3 arranged along the first direction D1 on the body portion BD, the thickness of the body portion BD in the third direction D3 may be smallest in the first unit cell region UC1 closest to the first contact pattern 181.

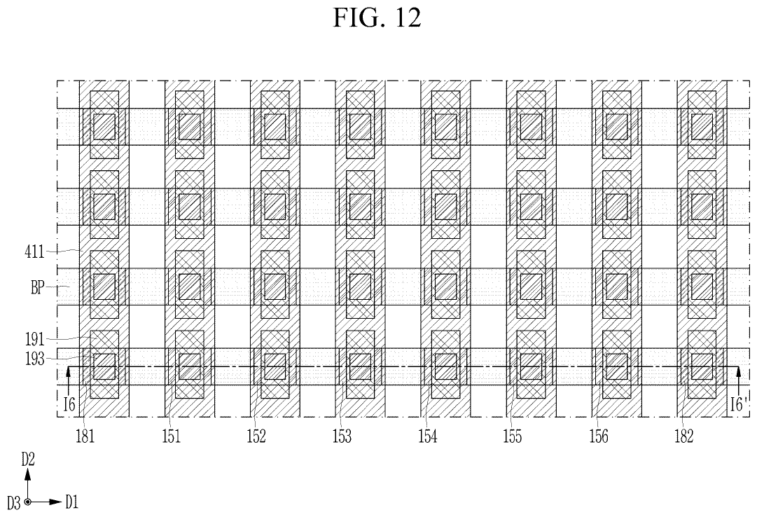

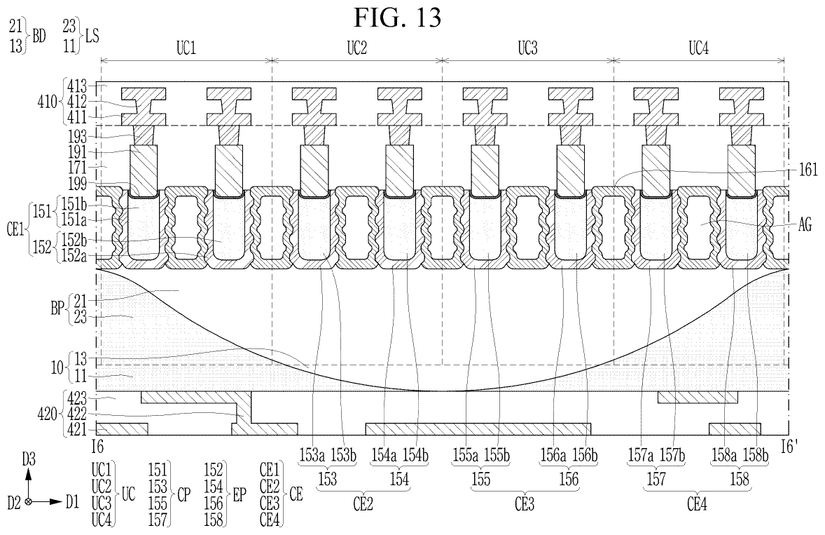

FIG. 12 and FIG. 13 are drawings for explaining a semiconductor device according to embodiments. Specifically, FIG. 12 is a plan view illustrating the semiconductor device according to embodiments, and FIG. 13 is a cross-sectional view of the semiconductor device taken along line 16-16′ of FIG. 12. The semiconductor device illustrated in FIG. 12 and FIG. 13 has substantially the same portions as the preceding embodiments, therefore, hereinafter, differences from the preceding embodiments will mainly be described. The semiconductor device shown in FIG. 12 and FIG. 13 may be partially different from the previous embodiments in that it does not include contact patterns 181 and 182.

Referring to FIG. 12 and FIG. 13, the semiconductor device according to embodiments may not include the contact patterns 181, 182 described with reference to FIG. 1 to FIG. 5. The semiconductor device according to embodiments may include a first unit cell region UC1, a second unit cell region UC2, a third unit cell region UC3, and a fourth unit cell region UC4 arranged along a first direction D1. The first unit cell region UC1 may be located at one end of the body portion BD extending along the first direction D1. The fourth unit cell region UC4 may be located at the other end of the body portion BD. The fourth unit cell region UC4 may include a fourth collector-emitter pair CE4 located on the body portion BD. The collector-emitter pair CE may include a fourth collector pattern 157 and a fourth emitter pattern 158 located spaced apart from one another along a first direction D1.

The fourth collector pattern 157 and the fourth emitter pattern 158 may each include a filling layer 157b, 158b and a liner layer 157a, 158a surrounding side surfaces and lower surfaces of the filling layer 157b, 158b. The filling layers 157b, 158b and the liner layers 157a, 158a are identical to the filling layers 151b, 152b, 153b, 154b, 155b, 156b and the liner layers 151a, 152a, 153a, 154a, 155a, 156a described with reference to FIG. 1 to FIG. 5, and therefore, a detailed description thereof will be omitted.

In embodiments, the thickness of the body portion BD in the third direction D3 may be the thickest at the middle point of the entire length of the body portion BD extending along the first direction D1, and may be the thinnest at both ends. In embodiments, the thickness of the body portion BD in the third direction D3 may gradually decrease from a middle point of the entire length of the body portion BD toward either the first unit cell region UC1 or the fourth unit cell region UC4.

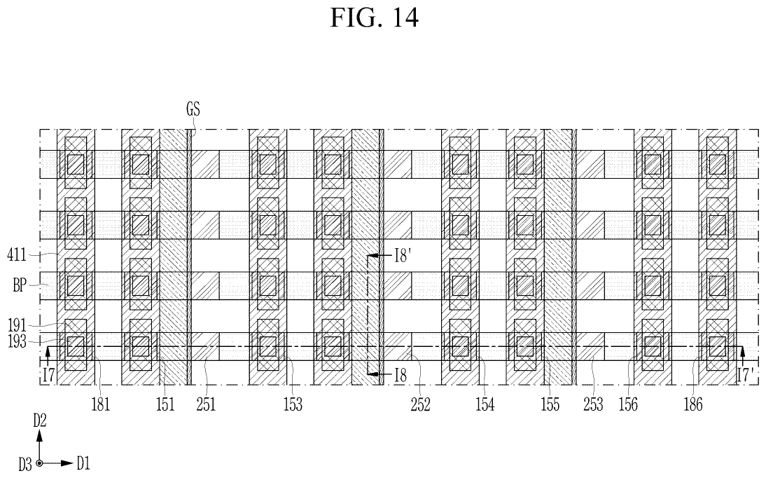

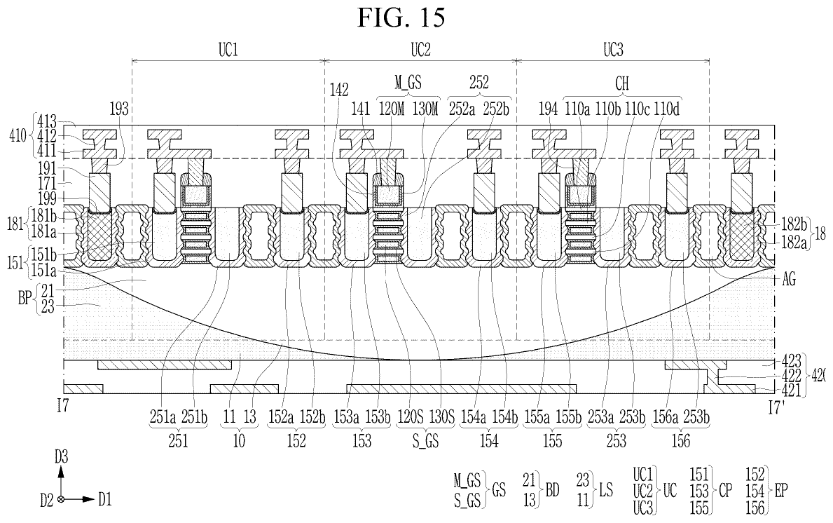

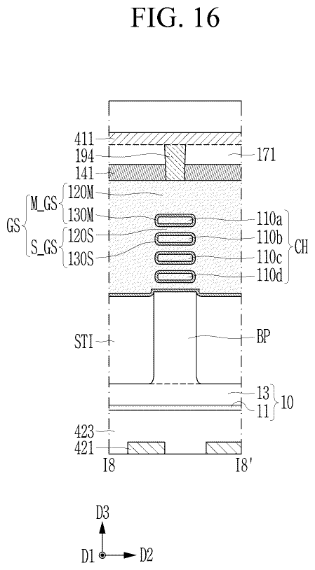

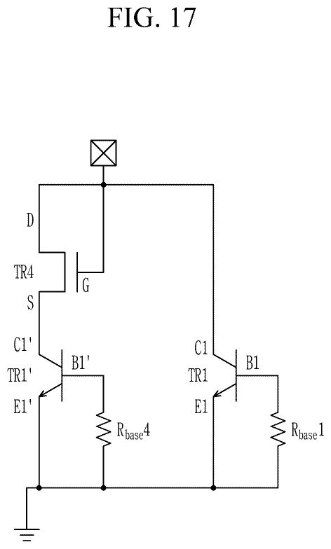

FIG. 14 to FIG. 17 are drawings for explaining a semiconductor device according to embodiments. Specifically, FIG. 14 is a plan view showing a semiconductor device according to embodiments, FIG. 15 is a cross-sectional view of the semiconductor device taken along line 17-17′ of FIG. 14, and FIG. 16 is a cross-sectional view of the semiconductor device taken along line 18-18′ of FIG. 14. FIG. 17 is a circuit diagram for explaining the operation of the semiconductor device according to the Example. The semiconductor device illustrated in FIG. 14 to FIG. 17 has many points in common with the previous embodiments, so hereinafter, differences from the previous embodiments will be mainly described. The semiconductor device according to embodiments may be partially different from the previous embodiments in that each of the unit cell regions UC1, UC2, UC3 includes a transistor structure.

Referring to FIG. 14 to FIG. 16, each of the unit cell regions UC1, UC2, UC3 of the semiconductor device according to embodiments may include sub collector patterns 251, 252, 253 located on the body portion BD, and gate structures GS, and channel structures CH.

The first sub collector pattern 251 may be located between the first collector pattern 151 and the first emitter pattern 152. The second sub collector pattern 252 may be located between the second collector pattern 153 and the second emitter pattern 154. The third sub collector pattern 253 may be located between the third collector pattern 155 and the third emitter pattern 156. In embodiments, the upper contact electrode 191 may not be located on the sub collector patterns 251, 252, 253. In embodiments, the sub collector patterns 251, 252, 253 may not be connected to the upper wiring 411 included in the upper wiring structure 410.

The sub collector patterns 251, 252, 253 included in the respective unit cell regions UC1, UC2, UC3 may include filling layers 251b, 252b, 253b and liner layers 251a, 252a, 253a surrounding side surfaces and lower surfaces of the filling layers 251b, 252b, 253b. A detailed description thereof will be omitted.

The sub collector patterns 251, 252, 253 may include semiconductor material. In embodiments, the sub collector patterns 251, 252, 253 may include the same semiconductor material as the collector patterns 151, 153, 155 and the emitter patterns 152, 154, 156. For example, the sub collector patterns 251, 252, 253 may include silicon (Si) or germanium (Ge). In addition, the sub collector patterns 251, 252, 253 may include, for example, a binary compound including at least two or more of carbon (C), silicon (Si), germanium (Ge), and tin (Sn), or a ternary compound. For example, the sub collector patterns 251, 252, 253 may include silicon (Si), silicon germanium (SiGe), germanium (Ge), silicon carbide (SIC), and the like, but are not limited thereto.

In embodiments, the sub collector patterns 251, 252, 253 may be doped with the same impurity as the collector patterns 151, 153, 155 and the emitter patterns 152, 154, 156.

The channel structures CH may be located on the upper surface of the body portion BD or the lower pattern BP. Referring to FIG. 1 and FIG. 2, the channel structures CH may be arranged spaced apart along the first direction D1 on the lower layer 10 and/or the body portion BD. A plurality of channel structures CH located on one body portion BD may be arranged spaced apart in the first direction D1. Each of the channel structures CH may include a first channel pattern 110a, a second channel pattern 110b, a third channel pattern 110c, and a fourth channel pattern 110d. The plurality of channel patterns 110a, 110b, 110c, 110d may be arranged spaced apart from one another in the third direction D3. As embodiments, each of the plurality of channel patterns 110a, 110b, 110c, 110d may have a sheet shape. Each of the channel patterns 110a, 110b, 110c, 110d may be a nano sheet having a thickness of several nanometers in the third direction D3.

The channel structures CH may provide a path through which current flows between the collector patterns 151, 153, 155 and the sub-collector patterns 251, 252, 253. In this case, the first collector pattern 151, the second collector pattern 153, and the third collector pattern 155 may function as drain patterns of the transistor structure. In this case, the first sub collector pattern 251, the second sub collector pattern 252, and the third sub collector pattern 253 may function as the source pattern of the transistor structure.

Referring to FIG. 15, the channel structures CH are disposed between the collector patterns 151, 153, 155 and the sub collector patterns 251, 252, 253, so that the collector patterns 151, 153, 155 and the sub collector patterns 251, 252, 253 may be connected.

The channel structures CH may penetrate a portion of the gate structure GS in a direction for example, a first direction D1 intersecting with the direction in which the gate structure GS extends, which will be described below. In FIG. 15 and FIG. 16, the channel structures CH are illustrated as each including four channel patterns 110a, 110b, 110c, 110d arranged apart from one another in the third direction D3. However, the present disclosure is not limited thereto, and the number of stacked channel patterns 110a, 110b, 110c, 110d included in one channel structure CH may be variously modified.

The channel structures CH may include a semiconductor material. For example, the channel structures CH may include Group IV semiconductors such as Si and Ge, Group III-V compound semiconductors, and Group II-VI compound semiconductors. In embodiments, the body portion BD may be located under the channel structure CH. The upper surface of the body portion BD may contact the lower surface of the sub-gate structure S_GS located at the lowest among the plurality of sub-gate structures S_GS.

The gate structure GS may be located on the lower layer 10. The body portion BD or the field insulating layer STI may be located between the gate structure GS and the lower layer 10. The gate structure GS may be extended on the lower layer 10 in a direction different from the direction in which the body portion BD is extended. For example, the gate structure GS may be extended on the lower layer 10 in the direction intersecting the direction in which the body portion BD extends for example, the second direction D2. The gate structures GS may be arranged spaced apart from one another in the first direction D1.

The gate structure GS may include the sub-gate structure S_GS and the main gate structure M_GS. The sub-gate structure S_GS is located on the lower layer 10, and the main gate structure M_GS may be located on the sub-gate structure S_GS. As illustrated in the cross-sectional view illustrated in FIG. 16, the main gate structure M_GS may be located on the field insulating layer STI. A side of the sub-gate structure S_GS may be covered by a portion of the main gate structure M_GS located on the field insulating layer STI. On the field insulating layer STI, the sub-gate structure S_GS may not be located. That is, a sub-gate structure S_GS may not be located between the main gate structure M_GS and the field insulating layer STI.

Each of the sub-gate structures S_GS may be formed of a plurality of layers. For example, each of the sub-gate structures S_GS may include a sub-gate electrode 120S and a sub-gate insulating layer 130S. The sub-gate structures S_GS and channel patterns 110a, 110b, 110c, 110d may be alternately stacked in the third direction D3. In FIG. 15 and FIG. 16, it is illustrated that four sub-gate structures S_GS are arranged spaced apart in the third direction D3, but the number of sub-gate structures S_GS that are arranged spaced apart is not limited thereto. For example, the gate structure GS may include three sub-gate structures S_GS.

The sub-gate electrode 120S may be located on the body portion BD. On the body portion BD, a plurality of sub-gate electrodes 120S may be located spaced apart. A plurality of sub-gate electrodes 120S and a plurality of channel patterns 110a, 110b, 110c, 110d may be alternately repeatedly stacked. At least one of the upper surface and the lower surface of the plurality of channel patterns 110a, 110b, 110c, 110d may be covered by the sub-gate electrode 120S. For example, the lower surface of the first channel pattern 110a may be covered by the sub-gate electrode 120S, and the upper surface of the fourth channel pattern 110d may be covered by the sub-gate electrode 120S. The upper surface and lower surface of each of the second channel pattern 110b and the third channel pattern 110c may be covered by the sub-gate electrode 120S.

The sub-gate electrode 120S may include at least one of a metal, a metal alloy, a conductive metal nitride, a metal silicide, a doped semiconductor material, a conductive metal oxide, and a conductive metal oxynitride. The sub-gate electrode 120S may include, for example, at least one selected from titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAIN), tantalum aluminum nitride (TaAIN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and a combination thereof, but is not limited thereto. Conductive metal oxide and conductive metal oxynitride may include the above-mentioned material in an oxidized form, but are not limited thereto.

The sub-gate insulating layer 130S may be located along the peripheries of the plurality of channel patterns 110a, 110b, 110c, 110d. The sub-gate insulating layer 130S may be in direct contact with the plurality of channel patterns 110a, 110b, 110c, 110d. The sub-gate insulating layer 130S may be interposed between the plurality of channel patterns 110a, 110b, 110c, 110d and the sub-gate electrode 120S. The sub-gate insulating layer 130S may include various insulating materials.

In one embodiment, the sub-gate insulating layer 130S is illustrated as a single layer; however, it is not limited thereto. For example, the sub-gate insulating layer 130S may be formed as a multilayer including silicon oxide (SiO₂) and a high dielectric constant material. At this time, the high dielectric constant material may include a material having a dielectric constant greater than that of silicon oxide (SiO₂), such as hafnium oxide (HfO), aluminum oxide (AlO), or tantalum oxide (TaO).

The main gate structure M_GS may be located on the sub-gate structure S_GS and the plurality of channel patterns 110a, 110b, 110c, 110d. The main gate structure M_GS may be located on an upper surface of an uppermost channel pattern 110a among a plurality of channel patterns 110a, 110b, 110c, 110d. The main gate structure M_GS may be located on the field insulating layer STI. The main gate structure M_GS may cover both side portions of the sub-gate structure S_GS.

The main gate structure M_GS may include a main gate electrode 120M and a main gate insulating layer 130M.

The main gate electrode 120M may be located on the sub-gate structure S_GS and the plurality of channel patterns 110a, 110b, 110c, 110d. The main gate electrode 120M may extend in a direction intersecting the body portion BD. At least a portion of the main gate electrode 120M may be located on the structure in which the sub-gate electrode 120S and the plurality of channel patterns 110a, 110b, 110c, 110d are alternately stacked. The remaining portion of the main gate electrode 120M may cover the side portion of a structure in which the sub-gate electrode 120S and the plurality of channel patterns 110a, 110b, 110c, 110d are alternately stacked. Four sides of each of the plurality of channel patterns 110a, 110b, 110c, 110d may be surrounded by the sub-gate electrode 120S and/or the main gate electrode 120M.

The main gate electrode 120M may include the same material as the sub-gate electrode 120S. For example, the main gate electrode 120M may include at least one selected from the group consisting of a metal, a metal alloy, a conductive metal nitride, a metal silicide, a doped semiconductor material, a conductive metal oxide, and a conductive metal oxynitride.

The main gate insulating layer 130M may be extended along the side portion of the main gate electrode 120M. The main gate insulating layer 130M may be extended along the side portion of the gate spacer 142 to be described below. The main gate insulating layer 130M may include various insulating materials. The main gate insulating layer 130M may include the same material as the sub-gate insulating layer 130S.

In one embodiment, the main gate insulating layer 130M is illustrated as a single layer, but is not limited thereto. For example, the main gate insulating layer 130M may be formed as a multilayer including silicon oxide (SiO₂) and a high dielectric constant material. At this time, the high dielectric constant material may include a material having a dielectric constant greater than that of silicon oxide (SiO₂), such as hafnium oxide (HfO), aluminum oxide (AIO), or tantalum oxide (TaO).

A semiconductor device according to embodiments may further include a capping layer 141 and a gate spacer 142.

The gate spacer 142 may be located on the side portion of the main gate electrode 120M. The gate spacer 142 may be located on the channel structure CH. The gate spacer 142 may not be located on the side portion of the sub-gate electrode 120S. The gate spacer 142 may not be located on the side portion of each of the channel patterns 110a, 110b, 110c, and 110d. The gate spacer 142 may not be disposed between the body portion BD and the plurality of channel patterns 110a, 110b, 110c, 110d. The gate spacer 142 may not be disposed between a plurality of channel patterns 110a, 110b, 110c, 110d adjacent to one another in the third direction D3. The gate spacer 142 is illustrated as being a single layer, but this is only for convenience of explanation and is not limited thereto.

The gate spacer 142 may include, for example, at least one selected from the group consisting of silicon nitride (SiNx), silicon oxynitride (SiON), silicon oxide (SiO₂), silicon oxycarbonitride (SiOCN), silicon boron nitride (SiBN), silicon oxyboronitride (SiOBN), silicon oxycarbide (SiOC), and combinations thereof.

The capping layer 141 may be located on the main gate structure M_GS and the gate spacer 142. The upper surface and side portion of the capping layer 141 may be covered by the interlayer insulating layer 171. Unlike what is illustrated, the capping layer 141 may be located between the gate spacers 142.

The capping layer 141 may include, for example, at least one selected from the group consisting of silicon nitride (SiNx), silicon oxynitride (SiON), silicon oxycarbonitride (SiOCN), silicon carbonitride (SiCN), and combinations thereof. The capping layer 141 may include a material having an etch selectivity with respect to the interlayer insulating layer 171.

The semiconductor device according to embodiments may further include a gate contact electrode 194. The gate contact electrode 194 may overlap with at least a portion of the gate structure GS in the third direction D3. The gate contact electrode 194 may be located between the upper wiring structure 410 and the gate structure GS. The gate contact electrode 194 may electrically connect the upper wiring 411 included in the upper wiring structure 410 and the gate structure GS. The lower surface of the gate contact electrode 194 may contact at least a portion of the upper surface of the main gate electrode 120M of the main gate structure M_GS. The upper surface of the gate contact electrode 194 may contact at least a portion of the lower surface of the upper wiring 411.

In embodiments, the gate structure GS may be electrically connected to the collector patterns 151, 153, 155 through the gate contact electrode 194. In embodiments, when an overvoltage is applied to the gate structure GS through the upper wiring 411 and the gate contact electrode 194 due to ESD, the transistor structure according to embodiments may be turned on.

The gate contact electrode 194 may include a conductive material. For example, the gate contact electrode 194 may include at least one selected from the group consisting of a metal, a metal alloy, a conductive metal nitride, a metal silicide, a doped semiconductor material, a conductive metal oxide, and a conductive metal oxynitride.

FIG. 17 may be a circuit diagram corresponding to at least a portion of the first unit cell region UC1 of FIG. 15.

In the semiconductor device according to embodiments, the first unit cell region UC1 may include two parasitic BJTs and one transistor structure. In FIG. 17, the first transistor TR1 and the first sub-transistor TR1′ are parasitic BJTs, and the fourth transistor TR4 may be a GAA FET or an MBCFET™.

The first transistor TR1 may include the first collector C1, the first emitter E1, and the first base B1. A first base resistance R_{base}1 may be located between the first base B1 and ground. The first collector C1 and the first emitter E1 may respectively correspond to the first collector pattern 151 and the first emitter pattern 152 of FIG. 15. The first base B1 may correspond to a portion of the body portion BD located in the first unit cell region UC1 of FIG. 15. The first base resistance R_{base}1 may correspond to a portion of the body portion BD between the first collector pattern 151 and the first emitter pattern 152 and the first contact pattern 181.

The first sub-transistor TR1′ may include a first sub-collector C1′, a first sub-emitter E1′, and a first sub-base B1′. A fourth base resistance R_{base}4 may be located between the first sub-base B1′ and ground. The first sub-collector C1′ may correspond to the first sub collector pattern 251 of FIG. 15. The first sub-emitter E1′ may correspond to the first emitter pattern 152 of FIG. 15. That is, the first emitter pattern 152 of FIG. 15 may correspond to both the first emitter E1 and the first sub-emitter E1′ of FIG. 17. The first sub-base B1′ may correspond to a portion of the body portion BD located in the first unit cell region UC1 of FIG. 15. The fourth base resistance R_{base}4 may correspond to a portion of the body portion BD between the first sub collector pattern 251 and the first emitter pattern 152 and the first contact pattern 181.

The fourth transistor TR4 may include a drain D, a source S, and a gate G. The drain D may correspond to the first collector pattern 151 of FIG. 15. That is, the first collector pattern 151 of FIG. 15 may correspond to both the first collector C1 and the drain D of FIG. 17. The source S may correspond to the first sub collector pattern 251 of FIG. 15. That is, the first sub collector pattern 251 of FIG. 15 may correspond to both the first sub-collector C1′ and the source S of FIG. 17. The gate G may correspond to the gate structure GS included in the first unit cell region UC1 of FIG. 15.

Referring to FIG. 17, the fourth transistor TR4 and the first sub-transistor TR1′ may be connected in series between the input terminal and ground. The first transistor TR1 is connected between the input terminal and ground, and may be connected in parallel with the fourth transistor TR4 and the first sub-transistor TR1′. Referring to FIG. 17, the drain D and the first collector C1 are connected to the input terminal, and the first sub-emitter E1′ and the first emitter E1 may be connected to ground. The source S may be directly connected to the first sub-collector C1′.

In embodiments, when an overcurrent is introduced through the input terminal due to ESD, a high voltage applied to the gate G may turn on the fourth transistor TR4, and may reverse-bias a PN junction between the first sub-collector C1′ and the first sub-base B1′ and a PN junction between a first collector C1 and a first base B1. When the applied voltage exceeds the breakdown voltage, the overcurrent may be discharged toward ground through the first sub-transistor TR1′ and the first transistor TR1.

According to embodiments, two parasitic BJTs may be located in one unit cell region UC, and the β value in the one unit cell region UC may be variously designed, thereby effectively controlling an operation of the parasitic transistor.

In the case of the second unit cell region UC2 and the third unit cell region UC3, since they include the same configurations as the first unit cell region UC1 and thus have the same operation, a detailed description thereof will be omitted.

While embodiments of the present disclosure have been described in detail above, the scope of rights of the present disclosure is not limited thereto, and various modifications and improvements using the basic concept of the present disclosure defined in the following claims by those skilled in the art also belong to the scope of rights of the present disclosure.

What is claimed is:

1. A semiconductor device comprising:
a lower layer including a lower insulating layer and a semiconductor layer located on at least a portion of an upper surface of the lower insulating layer;
a lower pattern located on the lower layer, wherein the lower pattern includes a first region comprising a semiconductor material and a second region located between the first region and the lower layer and comprising an insulating material, and a first collector pattern and a first emitter pattern spaced apart from one another in a first direction parallel to the upper surface of the lower layer;
wherein:
the semiconductor layer and the first region constitute at least a portion of a body portion, and
a first thickness of the body portion in a vertical direction under the first collector pattern is less than a second thickness of the body portion in the vertical direction under the first emitter pattern.

2. The semiconductor device of claim 1, comprising:
a first contact pattern located on the lower pattern and spaced apart from the first collector pattern in the first direction;
wherein the first collector pattern is located between the first contact pattern and the first emitter pattern, and a third thickness of the body portion in the vertical direction under the first contact pattern is less than the first thickness.

3. The semiconductor device of claim 2, wherein the first contact pattern is doped with a dopant of a conductivity type different from that of the first collector pattern and the first emitter pattern.

4. The semiconductor device of claim 2, wherein the first contact pattern and the first region are doped with a dopant of a same conductivity type.

5. The semiconductor device of claim 2, further comprising:
a first unit cell region located on the lower layer, a second unit cell region located in the first direction from the first unit cell region, and a third unit cell region located in the first direction from the second unit cell region,
wherein:
the first unit cell region includes the first collector pattern and the first emitter pattern,
the second unit cell region includes a second collector pattern and a second emitter pattern spaced apart in the first direction,
the third unit cell region includes a third collector pattern and a third emitter pattern spaced apart in the first direction, and
the semiconductor device further comprises a second contact pattern located on the lower pattern and spaced apart from the third emitter pattern in the first direction.

6. The semiconductor device of claim 5, wherein a fourth thickness of the body portion in the vertical direction under the third collector pattern is greater than a fifth thickness of the body portion in the vertical direction under the third emitter pattern.

7. The semiconductor device of claim 5, wherein a distance in the first direction between the second unit cell region and the first contact pattern is equal to a distance in the first direction between the second unit cell region and the second contact pattern.

8. The semiconductor device of claim 5, wherein between the first contact pattern and the second unit cell region, the thickness of the body portion in the vertical direction gradually increases toward the second unit cell region.

9. The semiconductor device of claim 5, wherein between the second unit cell region and the second contact pattern, the thickness of the body portion in the vertical direction gradually decreases away from the second unit cell region.

10. The semiconductor device of claim 5, wherein an average thickness of the body portion in the vertical direction in the first unit cell region is less than an average thickness in the second unit cell region.

11. The semiconductor device of claim 2, further comprising:
a first unit cell region located on the lower layer;
a second unit cell region located in the first direction from the first unit cell region; and
a third unit cell region located in the first direction from the second unit cell region;
wherein the thickness of the body portion in the vertical direction gradually increases from the first collector pattern toward the third unit cell region.

12. The semiconductor device of claim 1, further comprising:
a sub-collector pattern located between the first collector pattern and the first emitter pattern;
channel patterns located between the sub-collector pattern and the first collector pattern; and
a gate structure surrounding the channel patterns.

13. The semiconductor device of claim 12, wherein the gate structure is electrically connected to the first collector pattern.

14. The semiconductor device of claim 5, wherein:
between the first contact pattern and the second unit cell region, the semiconductor layer includes a portion where the thickness in the vertical direction gradually increases toward the second unit cell region; and
between the second unit cell region and the second contact pattern, the semiconductor layer includes a portion where the thickness gradually decreases away from the second unit cell region.

15. The semiconductor device of claim 1, further comprising:
an intermediate insulating layer located between the first collector pattern and the first emitter pattern, wherein the intermediate insulating layer includes an air gap.

16. A semiconductor device comprising:
a body portion;
a first contact pattern located on an upper surface of the body portion;
a second contact pattern spaced apart from the first contact pattern in a first direction; and
a plurality of collector-emitter pairs located between the first and second contact patterns and arranged in the first direction;
wherein:
the first and second contact patterns are located at opposite ends of the body portion;
each of the collector-emitter pairs includes a collector pattern and an emitter pattern spaced apart from one another in the first direction; and
the thickness of the body portion in the vertical direction gradually decreases from a middle collector-emitter pair among the plurality of collector-emitter pairs toward the first and second contact patterns.

17. The semiconductor device of claim 16, further comprising:
an intermediate insulating layer located between the collector pattern and the emitter pattern, wherein the intermediate insulating layer includes an air gap.

18. The semiconductor device of claim 16, wherein:
the first contact pattern is doped with a dopant of a conductivity type different from that of the collector pattern and the emitter pattern;
at least a portion of the body portion and the first contact pattern are doped with a dopant of a same conductivity type.

19. The semiconductor device of claim 16, further comprising:
a lower insulating structure covering a lower surface of the body portion, wherein the thickness of the lower insulating structure in the vertical direction gradually increases from a middle collector-emitter pair among the plurality of collector-emitter pairs toward the first and second contact patterns.

20. A semiconductor device comprising:
a first unit cell region,
a second unit cell region, and
a third unit cell region arranged on a lower layer along a first direction parallel to an upper surface of the lower layer,
wherein the semiconductor device comprises:
a lower pattern located on the lower layer and extending in the first direction, the lower pattern including a first region comprising a semiconductor material, and a second region located between the first region and the lower layer and comprising an insulating material;
a first collector pattern, a first emitter pattern, a second collector pattern, a second emitter pattern, a third collector pattern, and a third emitter pattern sequentially spaced apart in the first direction;
a first contact pattern located on the lower pattern and spaced apart from the first collector pattern in the first direction;
a second contact pattern located on the lower pattern and spaced apart from the third emitter pattern in the first direction;
intermediate insulating layers located between the collector patterns and the emitter patterns and including air gaps;
an upper wiring structure located over the collector patterns, the emitter patterns, and the contact patterns; and
upper contact electrodes connecting each of the collector patterns, emitter patterns, and contact patterns to the upper wiring structure;
wherein:
the first collector pattern is located between the first contact pattern and the first emitter pattern;
the third emitter pattern is located between the third collector pattern and the second contact pattern;
the first collector pattern and the first emitter pattern are included in the first unit cell region;
the second collector pattern and the second emitter pattern are included in the second unit cell region;
the third collector pattern and the third emitter pattern are included in the third unit cell region;
the lower layer includes a lower insulating layer and a semiconductor layer located on at least a portion of an upper surface of the lower insulating layer;
the semiconductor layer and the first region constitute at least a portion of a body portion;
the thickness of the body portion in the vertical direction gradually increases toward the second unit cell region from the first contact pattern; and
the thickness of the body portion in the vertical direction gradually decreases away from the second unit cell region toward the second contact pattern.
